(19) United States
(12) Patent Application Publication
(10) Pub. No.: US 2017/0187002 A1
(43) Pub. Date: Jun. 29, 2017

(54) ORGANIC LIGHT-EMITTING DEVICE

(71) Applicant: INDUSTRIAL TECHNOLOGY RESEARCH INSTITUTE, Hsinchu (TW)

(72) Inventors: Yueh-Chuan HUANG, Jhudong Township (TW); Chyi-Ming LEU, Jhudong Township (TW); Chih-Jen YANG, Taoyuan City (TW); Meng-Ting HSIEH, Kaohsiung City (TW)

(73) Assignee: INDUSTRIAL TECHNOLOGY RESEARCH INSTITUTE, Hsinchu (TW)

(21) Appl. No.: 15/167,308

(22) Filed: May 27, 2016

(30) Foreign Application Priority Data
Dec. 28, 2015 (TW) 104143992

(51) Int. Cl. H01L 51/52

(52) U.S. Cl. CPC H01L 51/5275; H01L 2251/301

(57) ABSTRACT

An organic light-emitting device is provided. The organic light-emitting device includes a substrate having a first surface and a second surface opposite to the first surface; an organic light-emitting element disposed on the first surface; and a low refractive index layer disposed on the second surface, wherein the low refractive index layer includes a mixture including polyvinylidene fluoride and inorganic nano-platelet, a hyperbranched polysiloxane, or a combination thereof.

### CROSS REFERENCE TO RELATED APPLICATIONS

The application is based on, and claims priority from, Taiwan Application Serial Number 104143992, filed on Dec. 28, 2015, the disclosure of which is hereby incorporated by reference herein in its entirety.

### TECHNICAL FIELD

The disclosure relates to an organic light-emitting device.

### BACKGROUND

The light-emitting element of an organic light-emitting diode (OLED) is generally composed of glass substrates, conductive electrodes made of indium tin oxide (ITO), and an organic light-emitting layer. No matter whether the type of OLED is “top-emitting” or “bottom-emitting”, the great difference between the refractive indexes of the materials used in the components results in reflection on the interface. This reflection in OLEDs may cause a low efficiency of light extraction. According to studies, in general OLEDs, almost a 70-80% loss of light, which cannot be guided outside the elements, is the result of the reflection on the interface. Since the difference of the refractive index of the materials used in OLEDs is too great, the total light-extraction efficiency may be improved by selecting the materials of the internal components of OLEDs or changing the structure thereof. However, by altering materials and structures, the accompanying change in the manufacturing process brings a greater challenge to the development of OLEDs.

### SUMMARY

According to an embodiment of the disclosure, the disclosure provides an organic light-emitting device including a substrate having a first surface and a second surface opposite to the first surface; an organic light-emitting element disposed on the first surface; and a low refractive index layer disposed on the second surface of the substrate, wherein the low refractive index layer comprises a mixture consisting of polyvinylidene fluoride and inorganic nano-platelet, a hyperbranched polysiloxane, or a combination thereof.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 is a cross-sectional view of the organic light-emitting device according to an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

The disclosure provides an organic light-emitting device including a low refractive index layer disposed on the outer side of the substrate (i.e. the light out-going surface). Since the low refractive index layer has a refractive index between about 1.3 and 1.5 and less than the refractive index of the substrate, the light totally reflected by the organic light-emitting element can be directed out of the organic light-emitting device, enhancing the external quantum efficiency of the organic light-emitting device. In addition, since the low refractive index layer can include a mixture consisting of polyvinylidene fluoride and inorganic nano-platelet, a hyperbranched polysiloxane, or a combination thereof, the low refractive index layer can be formed on the substrate by coating a low refractive index composition on the substrate to form a coating and subjecting the coating to a thermal treatment.

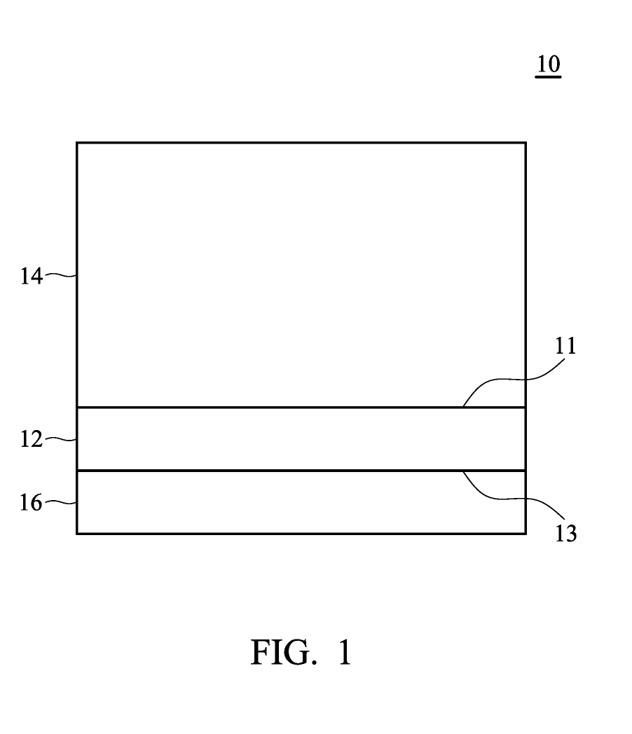

According to embodiments of the disclosure, as shown in FIG. 1, the organic light-emitting device of the disclosure 10 can include a substrate 12, wherein the substrate 12 has a first surface 11 and a second surface 13 opposite to the first surface 11. An organic light-emitting element 14 is disposed on the first surface 11 of the substrate 12. A low refractive index layer 16 is disposed on the second surface 13 of the substrate 12.

According to embodiments of the disclosure, the substrate 12 can be a glass substrate, ceramic substrate, or flexible substrate. In particular, the flexible substrate can be made of polyimide (PI), polycarbonate (PC), polyethersulfone (PES), polynorbornene (PNB), polyetherimide (PEI), polyethylene naphthalate (PEN), polyethylene terephthalate (PET), or a combination thereof. The substrate 12 of the disclosure can have a refractive index that is greater than the refractive index of the low refractive index layer.

According to embodiments of the disclosure, the organic light-emitting element 14 can include a light emitting layer. In addition, the organic light-emitting element 14 can further include a first electrode, a hole injection layer, a hole transport layer, an electron transport layer, an electron injection layer, and a second electrode. The layers, materials, and the thickness of the organic light-emitting element 14 of the disclosure are not limited and can be optionally modified by a person of ordinary skill in the field.

According to embodiments of the disclosure, the low refractive index layer of the disclosure can include a mixture consisting of polyvinylidene fluoride and inorganic nano-platelet, hyperbranched polysiloxane, or a combination thereof. For example, the low refractive index layer 16 can consist of a polyvinylidene fluoride and an inorganic nano-platelet uniformly distributed in the polyvinylidene fluoride, wherein the weight ratio between the polyvinylidene fluoride and the inorganic nano-platelet can be from about 20:80 to 97:3. Therefore, the low refractive index layer can have a refractive index between about 1.3 and 1.5, a light transmittance that is greater than about 85% (measured at a wavelength of 550 nm), a haze value that is less than about 2% (such as less than about 1%), and exhibit a high thermal resistance. In addition, the low refractive index layer can have a thickness between about 10 nm and 10 μm. The inorganic nano-platelet can include hydrogen ion exchanged smectite clay, vermiculite, halloysite, sericite, mica, synthetic mica, layered double hydroxide, synthetic smectite clay, or a combination thereof. The inorganic nano-platelet can have a length between 10 nm and 100 nm.

On the other hand, the low refractive index layer 16 can be hyperbranched polysiloxane. In addition, the low refractive index layer 16 can include the inorganic nano-platelet uniformly distributed in the hyperbranched polysiloxane. For example, the hyperbranched polysiloxane can be prepared by crosslinking an oligomer of 1 part by weight of a first silane and 0.05 to 20 parts by weight of a second silane. The first silicon can be Si(R¹)₂(OR²)₂, each R¹ is independently acrylic group, epoxy group, vinyl group, amino group, aromatic group, or aliphatic group, and each R² is independently aliphatic group. The second silicon can be Si(R³)(OR⁴)₃, R³ is acrylic group, epoxy group, vinyl group, amino group, aromatic group, or aliphatic group, and each R⁴ is independently aliphatic group. When the low refractive index layer is made of the hyperbranched polysiloxane, the low refractive index layer can have a yellow value (i.e. b value, under 300° C.) less than about 0.35.

According to embodiments of the disclosure, the low refractive index layer can be formed by the following steps. A coating of the low refractive index composition is formed on the substrate by spin coating, blade coating, or screen printing. The low refractive index composition can include a mixture consisting of polyvinylidene fluoride and inorganic nano-platelet, hyperbranched polysiloxane, or a combination thereof, distributed in an organic solvent. The organic solvent can be N-methyl-2-pyrrolidone (NMP), N,N-dimethylacetamide (DMAc), γ-butyrolactone (GBL), N,N-dimethylformamide (DMF), dimethyl sulfoxide (DMSO), xylene, toluene, or a combination thereof. Next, the coating is subjected to a thermal treatment, obtaining the low refractive index layer. The thermal treatment can include a single-section baking process or multi-section baking process. For example, the coating can be baked at 50-70° C. for 5-15 minutes, and then baked at 120-180° C. for 10-60 minutes.

Below, exemplary embodiments will be described in detail so as to be easily realized by a person having ordinary knowledge in the art. The disclosure concept may be embodied in various forms without being limited to the exemplary embodiments set forth herein. Descriptions of well-known parts are omitted for clarity.

### Preparation Example 1

10 g of polyvinylidene fluoride (PVDF) was added into a reaction bottle and dissolved in 90 g of dimethylacetamide (DMAC). After stirring, a polyvinylidene fluoride solution (10 wt %) was obtained.

### Preparation Example 2

25 g of clay (Laponite RDS, particle size of 20 nm×20 nm×1 nm) was dispersed in 1000 g of deionized water, obtaining a clay aqueous dispersion. Next, 300 g of an H-form cation ion-exchange resin (Dowex H form) and 300 g of OH from anion ion-exchange resin (Dowex OH form) were added to the clay aqueous dispersion to perform ion-exchange. Then, the above clay aqueous dispersion was thoroughly mixed with 1440 g of isopropanol. A portion of the isopropanol and water were removed by vacuum decompression concentration and 2.5 wt % of an isopropanol dispersion was obtained. Next, 600 g of dimethylacetamide (DMAC) was added to the isopropanol dispersion. The remaining portion of water and isopropanol were removed by vacuum decompression concentration and 4 wt % of clay DMAc dispersion was obtained. Next, 10 g of polyvinylidene fluoride of Preparation Example 1 and 2.78 g of the above clay DMAc dispersion were added into a reaction bottle. After stirring, a low refractive index composition (1) was obtained, wherein the weight ratio between the clay and the polyvinylidene fluoride was about 1:9.

### Preparation Example 3

25 g of clay (Laponite RDS, particle size of 20 nm×20 nm×1 nm) was dispersed in 1000 g of deionized water, obtaining a clay aqueous dispersion. Next, 300 g of an H-form cation ion-exchange resin (Dowex H form) and 300 g of OH from anion ion-exchange resin (Dowex OH form) were added to the clay aqueous dispersion to perform ion-exchange. Then, the above clay aqueous dispersion was thoroughly mixed with 1440 g of isopropanol. A portion of the isopropanol and water was removed by vacuum decompression concentration and 2.5 wt % of an isopropanol dispersion was obtained. Next, 600 g of dimethylacetamide (DMAC) was added to the isopropanol dispersion. The remaining portion of water and isopropanol was removed by vacuum decompression concentration and 4 wt % of clay DMAc dispersion was obtained. Next, 10 g of polyvinylidene fluoride of Preparation Example 1 and 6.25 g of the above clay DMAc dispersion were added into a reaction bottle. After stirring, a low refractive index composition (2) was obtained, wherein the weight ratio between the clay and the polyvinylidene fluoride was about 2:8.

### Preparation Example 4

12.5 g of dimethyldimethoxy silane, 30 g of isopropanol (isopropyl alcohol), 7.6 g of deionized water, and 3 g of hydrochloric acid (HCl, 0.01M) were added into a reaction bottle. After stirring at room temperature for 1.5 hours, 37.5 g of methyltrimethoxy silane) was added into the reaction bottle. After stirring for 1.5 hours, a portion of the isopropanol was removed by vacuum decompression concentration, obtaining a low refractive index composition (3).

Preparation and Characteristic of Low Refractive Index Layer

### Example 1

A coating of the low refractive index composition (1) of Preparation Example 2 was formed on the glass substrate by blade coating. After baking at 150° C. for 10 minutes, a low refractive index layer (1) with a thickness of about 600 nm was obtained. Next, the refractive index, light transmittance (at a wavelength of 550 nm), and b value (under varying temperatures) of the low refractive index layer (1) were measured, and the results are shown in Table 1.

### Example 2

A coating of the low refractive index composition (2) of Preparation Example 3 was formed on the glass substrate by blade coating. After baking at 150° C. for 10 minutes, a low refractive index layer (2) with a thickness of about 600 nm was obtained. Next, the refractive index, light transmittance (at a wavelength of 550 nm), and b value (under varying temperatures) of the low refractive index layer (2) were measured, and the results are shown in Table 1.

### Example 3

A coating of the low refractive index composition (3) of Preparation Example 4 was formed on the glass substrate by blade coating. After baking at 210° C. for 30 minutes, a low refractive index layer (3) with a thickness of about 600 nm was obtained. Next, the refractive index, light transmittance (at a wavelength of 550 nm), and b value (under varying temperatures) of the low refractive index layer (3) were measured, and the results are shown in Table 1.

### Comparative Example 1

A coating of polyvinylidene fluoride solution of Preparation Example 1 was formed on the glass substrate by blade coating. After baking at 150° C. for 10 minutes, a polyvinylidene fluoride layer (1) with a thickness of about 600 nm was obtained. Next, the refractive index, light transmittance (at a wavelength of 550 nm), and b value (under varying temperatures) of the polyvinylidene fluoride layer (1) were measured, and the results are shown in Table 1.

TABLE 1

| | | light | b value | | |
|---|---|---|---|---|---|
| | refrac- | transmit- | (room | b value | b value |
| | tive | tance | temper- | (at | (at |
| | index | (@550 nm) | ature) | 230° C.) | 300° C.) |
| low refrac- | 1.40 | >90% | 0.31 | 0.40 | — |
| tive index | | | | | |
| layer (1) | | | | | |
| low refrac- | 1.44 | >90% | 0.30 | 0.40 | — |
| tive index | | | | | |
| layer (2) | | | | | |
| low refrac- | 1.46 | >90% | 0.30 | 0.30 | 0.31 |
| tive index | | | | | |
| layer (3) | | | | | |
| polyvinyl- | 1.38 | >70% | 0.50 | 0.60 | — |
| idene fluoride | | | | | |
| layer (1) | | | | | |

As shown in Table 1, since the low refractive index layer of the disclosure has a specific weight ratio of the polyvinylidene fluoride and the inorganic nano-platelet, the low refractive index layers (1) and (2) of Examples (1) and (2) exhibits superior light transmittance, lower b value, and higher thermal stability in comparison with the polyvinylidene fluoride layer of Comparative Example 1. Furthermore, since the low refractive index layer of the disclosure can consist of the hyperbranched polysiloxane, the low refractive index layer (3) of Example 3 exhibits high thermal stability and low b value (i.e. having low tendency toward yellowing after baking at 300° C.).

Preparation of Organic Light-Emitting Device

### Example 4

A glass substrate with an indium tin oxide (ITO) film (with a thickness of 120 nm) formed on the first surface of the substrate was provided and then washed with a cleaning agent, acetone, and isopropanol with ultrasonic agitation. After drying with a nitrogen flow, the ITO film was subjected to a UV/ozone treatment for 30 minutes. Next, NPB (N,N′-di(naphthalene-1-yl)-N,N′-diphenyl-benzidine, with a thickness of 50 nm), CBP (4,4′-N,N′-dicarbazole-biphenyl) doped with Irppy₃ (tris(2-phenylpyridine) iridium) (the ratio between CBP and Irppy₃ was 96:4, with a thickness of 10 nm), BCP (2,9-dimethyl-4,7-diphenyl-1,10-phenanthroline, with a thickness of 10 nm), Alq₃ (tris (8-hydroxyquinoline) aluminum, with a thickness of 35 nm), LiF (with a thickness of 0.5 nm), and Al (with a thickness of 120 nm) were subsequently formed on the ITO film at 10⁻⁶ Pa, wherein the ITO film, NPB, CBP:Irppy₃, BCP, Alq₃, LiF, and Al composed the organic light-emitting element. After packaging, the organic light-emitting device (1) was obtained. The materials and layers formed therefrom are described in the following: ITO/NPB(50 nm)/CBP:Irppy₃(10 nm, 4%)/BCP(10 nm)/Alq₃(35 nm)/LiF(0.5 nm)/Al(120 nm)

The current efficiency of the organic light-emitting device (1) was measured at a brightness of 1000 cd/m². The result is shown in Table 2.

### Example 5

A coating of the low refractive index composition (1) of Preparation Example 2 was formed on the second surface (opposite to the first surface) of the substrate by blade coating. Next, the coating was baked at 150° C. for 10 minutes, obtaining a low refractive index layer (with a thickness of 600 nm) formed on the second surface of the substrate. Next, an organic light-emitting element was formed on the first surface of the substrate, obtaining the organic light-emitting device (2). In particular, the organic light-emitting element was the same as the organic light-emitting element of Example 4. The low refractive index layer of the organic light-emitting device (2) was separated from the organic light-emitting element by the substrate.

The current efficiency of the organic light-emitting device (2) was measured at a brightness of 1000 cd/m². The result is shown in Table 2.

### Example 6

Example 6 was performed in the same manner as Example 5 except that the thickness of the low refractive index layer was increased from 600 nm to about 900 nm, obtaining the organic light-emitting device (3).

The current efficiency of the organic light-emitting device (3) was measured at a brightness of 1000 cd/m². The result is shown in Table 2.

### Example 7

A coating of the low refractive index composition (2) of Preparation Example 3 was formed on the second surface (opposite to the first surface) of the substrate by blade coating. Next, the coating was baked at 150° C. for 10 minutes, obtaining a low refractive index layer (with a thickness of 600 nm) formed on the second surface of the substrate. Next, an organic light-emitting element was formed on the first surface of the substrate, obtaining the organic light-emitting device (4). In particular, the organic light-emitting element was the same as the organic light-emitting element of Example 4. The low refractive index layer of the organic light-emitting device (4) was separated from the organic light-emitting element by the substrate.

The current efficiency of the organic light-emitting device (4) was measured at a brightness of 1000 cd/m². The result is shown in Table 2.

### Example 8

Example 8 was performed in the same manner as Example 7 except that the thickness of the low refractive index layer was increased from 600 nm to about 900 nm, obtaining the organic light-emitting device (5).

The current efficiency of the organic light-emitting device (5) was measured at a brightness of 1000 cd/m². The result is shown in Table 2.

### Example 9

A coating of the low refractive index composition (3) of Preparation Example 4 was formed on the second surface (opposite to the first surface) of the substrate by blade coating. Next, the coating was baked at 210° C. for 30 minutes, obtaining a low refractive index layer (with a thickness of 860 nm) formed on the second surface of the substrate. Next, an organic light-emitting element was formed on the first surface of the substrate, obtaining the organic light-emitting device (6). In particular, the organic light-emitting element was the same as the organic light-emitting element of Example 4. The low refractive index layer of the organic light-emitting device (6) was separated from the organic light-emitting element by the substrate.

The current efficiency of the organic light-emitting device (6) was measured at a brightness of 1000 cd/m². The result is shown in Table 2.

### Example 10

Example 10 was performed in the same manner as Example 9 except that the thickness of the low refractive index layer was reduced from 860 nm to about 740 nm, obtaining the organic light-emitting device (7).

The current efficiency of the organic light-emitting device (7) was measured at a brightness of 1000 cd/m². The result is shown in Table 2.

TABLE 2

| | current efficiency | efficiency promotion |
|---|---|---|
| | (Cd/A) (measured | (in comparison with |
| | at a brightness | organic light- |
| | of 1000 cd/m²) | emitting device (1)) |
| organic light- | 21.66 | — |
| emitting device (1) | | |
| organic light- | 24.42 | +12.74% |
| emitting device (2) | | |
| organic light- | 24.14 | +11.45% |
| emitting device (3) | | |
| organic light- | 24.79 | +14.45% |
| emitting device (4) | | |
| organic light- | 24.06 | +11.08% |
| emitting device (5) | | |
| organic light- | 24.65 | +13.80% |
| emitting device (6) | | |
| organic light- | 24.42 | +12.74% |
| emitting device (7) | | |

As shown in Table 2, when the low refractive index layer of the disclosure is formed on the light extracting side surface of the substrate of the organic light-emitting device, the difference between the refractive index of the substrate and the refractive index of air can be reduced, resulting in reducing the chance of total internal reflection by changing the direction of light. As a result, the current efficiency of the organic light-emitting device of the disclosure is 1.11-1.14 times greater than that of the organic light-emitting device without the low refractive index layer of the disclosure. In addition, when the low refractive index layer includes a mixture consisting of polyvinylidene fluoride and inorganic nano-platelet, hyperbranched polysiloxane, or a combination thereof, the low refractive index layer can be formed on the substrate by coating a low refractive index composition on the substrate to form a coating and subjecting the coating to a thermal treatment.

It will be clear that various modifications and variations can be made to the disclosed methods and materials. It is intended that the specification and examples be considered as exemplary only, with the true scope of the disclosure being indicated by the following claims and their equivalents.

What is claimed is:

1. An organic light-emitting device, comprising:
a substrate having a first surface and a second surface opposite to the first surface;
an organic light-emitting element disposed on the first surface; and
a low refractive index layer disposed on the second surface, wherein the low refractive index layer comprises a mixture consisting of polyvinylidene fluoride and inorganic nano-platelet, a hyperbranched polysiloxane, or a combination thereof.

2. The organic light-emitting device as claimed in claim 1, wherein the low refractive index layer has a refractive index between 1.3 and 1.5.

3. The organic light-emitting device as claimed in claim 1, wherein the low refractive index layer has a light transmittance greater than 85%.

4. The organic light-emitting device as claimed in claim 1, wherein the low refractive index layer has a thickness between 10 nm and 10 μm.

5. The organic light-emitting device as claimed in claim 1, wherein the low refractive index layer has a haze value less than 2%.

6. The organic light-emitting device as claimed in claim 1, wherein the substrate is a glass substrate, ceramic substrate, or flexible substrate.

7. The organic light-emitting device as claimed in claim 6, wherein the flexible substrate is made of polyimide, polycarbonate, polyethersulfone, polynorbornene, polyetherimide, polyethylene naphthalate, polyethylene terephthalate, or a combination thereof.

8. The organic light-emitting device as claimed in claim 1, wherein the low refractive index layer is the mixture consisting of polyvinylidene fluoride and inorganic nano-platelet, and the weight ratio of the polyvinylidene fluoride and the inorganic nano-platelet is from 80:20 to 97:3.

9. The organic light-emitting device as claimed in claim 8, wherein the inorganic nano-platelet comprises hydrogen ion exchanged smectite clay, vermiculite, halloysite, sericite, mica, synthetic mica, layered double hydroxide, synthetic smectite clay, or a combination thereof.

10. The organic light-emitting device as claimed in claim 1, wherein the low refractive index layer has a refractive index lower than the refractive index of the substrate.
